(19) United States
(12) Patent Application Publication
(10) Pub. No.: US 2026/0087227 A1
(43) Pub. Date: Mar. 26, 2026

(54) INTEGRATED CIRCUIT DESIGN METHOD AND SYSTEM

(71) Applicant: SAMSUNG ELECTRONICS CO., LTD., Suwon-si (KR)

(72) Inventors: WOONG-GYU LEE, Suwon-si (KR); Taehyung Lee, Suwon-si (KR)

(73) Assignee: SAMSUNG ELECTRONICS CO., LTD., Suwon-si (KR)

(21) Appl. No.: 19/229,334

(22) Filed: Jun. 5, 2025

(30) Foreign Application Priority Data
Sep. 24, 2024 (KR) 10-2024-0129045
Jan. 22, 2025 (KR) 10-2025-0009502

(51) Int. Cl. G06F 30/398; G06F 30/392

(52) U.S. Cl. CPC G06F 30/398; G06F 30/392

(57) ABSTRACT

An integrated circuit design system includes a storage device that stores a cell library including layout information of standard cells and a local layout effect (LLE) model, and one or more processors that execute a design module to cause the one or more processors to generate a layout of an integrated circuit including the standard cells based on the cell library, extract LLE parameters for a transistor in the integrated circuit from a layout versus schematic (LVS) netlist corresponding to the layout, and calculate variations of physical characteristics of the transistor according to the LLE parameters based on the LLE parameters and the LLE model.

### CROSS-REFERENCE TO RELATED APPLICATION

This application claims priority to Korean Patent Application No. 10-2024-0129045, filed Sep. 24, 2024, and to Korean Patent Application No. 10-2025-0009502 filed Jan. 22, 2025, in the Korean Intellectual Property Office, the entire contents of which being incorporated by preference herein.

### BACKGROUND

Integrated circuits that process digital signals may be designed based on standard cells containing transistors. A functional circuit may be formed by placing and routing standard cells so that the integrated circuit implements the desired function.

The demand for high performance, high speed, and/or multi-functionality in semiconductor devices is increasing, and the integration level of semiconductor devices is increasing. As semiconductor devices become more highly integrated, the electrical characteristics of transistors within an integrated circuit may vary depending on the surrounding structure. This effect of the surrounding layout is referred to as the Local Layout Effect (LLE).

### SUMMARY

It is an aspect to provide an integrated circuit design method and system for performing Local Layout Effect (LLE) analysis on transistors within an integrated circuit.

According to an aspect of one or more embodiments, there is provided an integrated circuit design system comprising a storage device configured to store a cell library including layout information of standard cells and a local layout effect (LLE) model; and at least one processor configured to execute a design module to cause the at least one processor to generate a layout of an integrated circuit including the standard cells based on the cell library, extract a plurality of LLE parameters for a transistor in the integrated circuit from a layout versus schematic (LVS) netlist corresponding to the layout, and calculate variations of physical characteristics of the transistor according to the plurality of LLE parameters based on the plurality of LLE parameters and the LLE model.

According to another aspect of one or more embodiments, there is provided a method for design an integrated circuit, the method comprising generating a layout design for the integrated circuit; obtaining a local versus schematic (LVS) netlist corresponding to the layout design; extracting a plurality of local layout effect (LLE) parameters for transistors in the integrated circuit from the LVS netlist; calculating variations of physical characteristics of the transistors based on the plurality of LLE parameters and an LLE model; and performing a post-layout simulation for the layout design.

According to yet another aspect of one or more embodiments, there is provided an integrated circuit design system comprising a storage device configured to store a cell library including layout information of standard cells and a local layout effect (LLE) model; at least one processor configured to execute a design module to cause the at least one processor to generate a layout of an integrated circuit including the standard cells based on the cell library; an analysis module configured to generate a local versus schematic (LVS) netlist corresponding to the layout; and a LLE module configured to perform an LLE analysis for transistors in the integrated circuit, based on LLE parameters extracted from the LVS netlist and the LLE model.

### BRIEF DESCRIPTION OF THE DRAWINGS

The above and other aspects will become more clear from the following description taken in conjunction with the drawings, in which:

FIG. 1 is a flowchart showing a design method of an integrated circuit according to some embodiments;

FIG. 2 is a diagram showing a design system for an integrated circuit according to some embodiments;

FIG. 3 is a block diagram of a Local Layout Effect (LLE) module according to some embodiments;

FIG. 4 is a diagram for explaining an LLE parameter extractor according to some embodiments;

FIG. 5 is a circuit diagram of an exemplary standard cell;

FIG. 6 is a layout diagram of a standard cell according to the circuit diagram of FIG. 5;

FIG. 7 shows a schematic layout versus schematic (LVS) netlist corresponding to the circuit diagram of FIG. 5 and the layout diagram of FIG. 6, according to some embodiments;

FIG. 8 is a diagram for explaining the LLE parameters, according to some embodiments;

FIG. 9 shows an exemplary LLE parameter file output by the LLE parameter extractor, according to some embodiments;

FIG. 10 is a diagram for explaining an LLE calculator according to some embodiments.

FIG. 11 is a diagram for explaining the operation method of an LLE model, according to some embodiments;

FIG. 12 shows an exemplary report file output by the LLE calculator, according to some embodiments;

FIG. 13 is a diagram for explaining a result output method of an integrated circuit design tool according to some embodiments;

FIG. 14 is a flowchart for explaining an LLE analysis method of an LLE module according to some embodiments;

FIG. 15 is a flowchart showing a method for designing and manufacturing an integrated circuit according to some embodiments;

FIG. 16 is a block diagram showing a design system for an integrated circuit according to some embodiments; and

FIG. 17 is a block diagram showing an electronic system according to some embodiments.

### DETAILED DESCRIPTION

Hereinafter, with reference to the attached drawings, various embodiments will be described in more detail. For identical components in the drawings, the same reference numerals are used, and duplicate descriptions of identical components are omitted for conciseness.

Accordingly, the drawings and description are to be regarded as illustrative in nature and not restrictive. Like reference numerals designate like elements throughout the specification. In order to clearly explain the in the various embodiments with respect to the drawings, parts that are not related to the explanation are omitted, and similar parts are given similar drawing reference numerals throughout the specification and drawings. In the flowcharts described with reference to the drawings, the order of operations is exemplary and may be changed, several operations may be merged, some operations may be split, and certain operations may be omitted or not be performed.

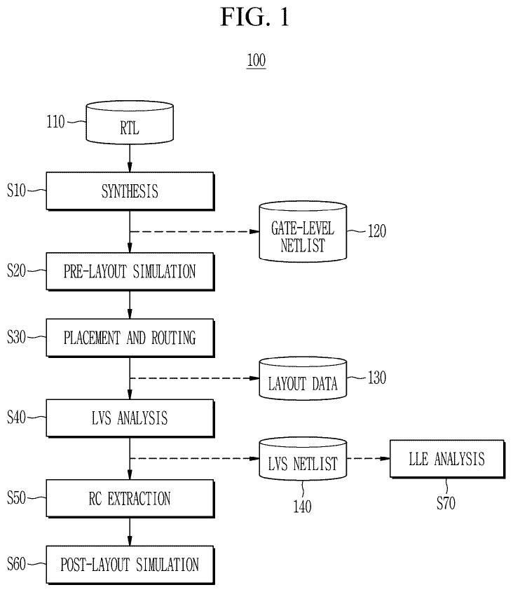

FIG. 1 is a flowchart showing a design method of an integrated circuit according to some embodiments.

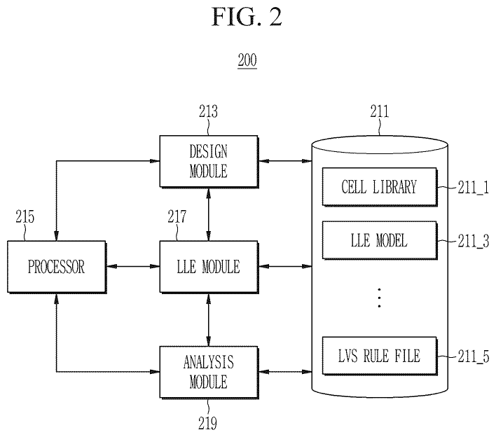

Referring to FIG. 1, a design method 100 of an integrated circuit may include operations of generating a gate level netlist 120, designing layout data 130 for a circuit, and verifying the same, and may be performed in a design tool (e.g., an EDA tool) for designing and verifying an integrated circuit. A design system including a design tool for an integrated circuit that performs a design method 100 for an integrated circuit is described in more detail in FIG. 2.

A design method 100 of an integrated circuit may include operations of logic synthesis S10, a pre-layout simulation S20, a placement and routing S30, a Layout Versus Schematic (LVS) analysis S40, a resistance and capacitance (RC) extraction S50, and a post-layout simulation S60.

The operation of logic synthesis S10 may refer to an operation of generating a gate level netlist 120 from RTL data 110. For example, an integrated circuit design tool (e.g., a logic synthesis tool) may perform logic synthesis to generate a gate level netlist 120 from RTL data 110 written as a hardware description language (HDL), such as VHSIC Hardware Description Language (VHDL) and Verilog. A gate level netlist 120 may refer to a logical schematic that expresses the connection relationship between gates within an integrated circuit.

The operation of pre-layout simulation S20 may be performed to determine whether the design of the integrated circuit satisfies specifications. The specifications may be predetermined. The operation of pre-layout simulation S20 may be performed by an integrated circuit simulation tool (e.g., Simulation Program with Integrated Circuit Emphasis, SPICE). If the design of an integrated circuit does not meet the specifications, the integrated circuit may be redesigned. The performance of the integrated circuit may be verified through the operation of pre-layout simulation S20. For example, the performance of an integrated circuit may be measured by inputting different signals into the circuit diagram.

In the operation of placement and routing S30, the standard cells may be placed. For example, an integrated circuit design tool (e.g., P&R tool) may place the standard cells used in gate level netlist 120. Here, standard cells may include logic elements such as AND, OR, inverters, and/or memory elements such as flip-flops. A standard cell may be implemented by at least one transistor, a (Metal Oxide Semiconductor Field Effect transistor (MOSFET), a FinFET, etc., but embodiments are not limited thereto. In the operation of placement and routing S30, the integrated circuit design tool may connect standard cells. For example, an integrated circuit design tool may generate interconnections that electrically connect the placed standard cells and may generate layout data 130 that defines the placed standard cells and the generated interconnections. The layout data 130 may have a format such as GDSII, for example, and may include geometric information of cells and interconnections.

The operation of LVS analysis S40 may be performed to verify whether the generated layout corresponds to the schematic. Specifically, an integrated circuit design tool (e.g., an LVS verification tool) may generate an LVS netlist 140 from layout data 130. The LVS netlist 140 may include patterns of the layout and connection information between the patterns. An integrated circuit design tool may compare the LVS netlist 140 with a schematic netlist that defines the interconnections of devices within the layout. If the LVS netlist 140 and the schematic netlist match within a matching tolerance range, LVS verification may be terminated. However, validation of the layout is not limited to this.

In the operation of resistance and capacitance (RC) extraction S50, the integrated circuit design tool may extract the resistance and capacitance for the interconnections of layout. Based on the resistance and capacitance extracted in the operation of RC extraction S50, parasitic parameters for interconnections of the layout for subsequent simulations, such as parasitic resistance and parasitic capacitance, may be determined.

The operation of post-layout simulation S60 may be performed to determine whether the design of the integrated circuit satisfies specifications. The specifications may be predetermined. The operation of post-layout simulation S60 may be performed by an integrated circuit simulation tool. Unlike pre-layout simulation, post-layout simulation may take into account the locations, distances, and other physical characteristics of elements in the layout. In the operation of post-layout simulation S60, parasitic resistance and parasitic capacitance for interconnections of the layout may be considered.

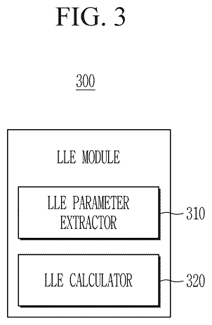

In some embodiments, the design method 100 of an integrated circuit may further include an operation of Local Layout Effect (LLE) analysis S70. As semiconductor processes become more sophisticated, the electrical characteristics of transistors within an integrated circuit may vary depending on their surrounding structures (e.g., adjacent components, metal wiring, transistor density, etc.). This effect of the surrounding layout is referred as a local layout effect (LLE). In some embodiments, the integrated circuit design tool may analyze LLE for transistors within the integrated circuit based on the LVS netlist 140 generated in the operation of LVS analysis S40. The integrated circuit design tool may analyze the LLE for transistors within the integrated circuit based on the LVS netlist 140 prior to performing the operation of post-layout simulation S60. Specifically, the integrated circuit design tool may extract LLE parameters for transistors from the LVS netlist 140 and use an LLE model to calculate variations in physical characteristics of the transistors depending on the values of the LLE parameters. A specific description of the operation of LLE analysis S70 is described below with reference to FIG. 3 to FIG. 14.

FIG. 2 is a diagram showing a design system for an integrated circuit according to some embodiments.

The design system 200 may include a storage device 211, a design module 213, a processor 215, an LLE module 217, and an analysis module 219. The design system 200 of FIG. 2 may perform at least a part of the design operations of the integrated circuit described in each operation of the design method 100 of the integrated circuit of FIG. 1. The design system 200 may be implemented as an integrated device and may thus be referred to as a design device. The design system 200 may be provided as a dedicated device for designing integrated circuits, but may also be a computer for driving various simulation tools or design tools.

In some embodiments, the storage device 211 may include a cell library 211_1, an LLE model 211_3, and an LVS rule file 211_5. The cell library 211_1, LLE model 211_3, and LVS rule file 211_5 may be provided from the storage device 211 to the design module 213, the LLE module 217, and the analysis module 219. Each module may be a program or software module comprising a plurality of instructions executed by the processor 215 and may be stored in a computer-readable storage medium.

In some embodiments, the cell library 211_1 may include various information about standard cells. The cell library 211_1 may include layout information such as height and size information for standard cells and timing information for standard cells. The design module 213 may receive a cell library 211_1 from the storage device 211 to perform the operation of placement and routing (S30 of FIG. 1). The number of cell libraries included in the storage device 211 may be varied.

In some embodiments, the LLE model 211_3 may be implemented as a function that calculates variations in physical characteristics of transistors in an integrated circuit according to LLE. In some embodiments, the LLE module 217 may perform the operation of LLE analysis (S70 of FIG. 1) using the LLE model 211_3. Specifically, the LLE module 217 may calculate the variation of physical characteristics of transistors in an integrated circuit according to LLE parameters using the LLE model 211_3. The LLE module 217 may use the LLE model 211_3 to calculate the variation in the physical characteristics of transistors in an integrated circuit according to LLE parameters and output information about the variations in the physical characteristics of the transistors. The information about variations in the physical characteristics of the transistors may include, but is not limited to, variations in a threshold voltage of the transistors and variations in a mobility of the transistors. Although the LLE module 217 is depicted in FIG. 2 as being separate from the design module 213, in some embodiments, the LLE module 217 may be included in the design module 213.

In some embodiments, the LVS rule file 211_5 may include codes written in accordance with, for example, aStandard Verification Rule Format (SVRF) or a TCL Verification Format (TVF). The LVS rule file 211_5 may define various elements such as transistors in the layout of an integrated circuit, and the analysis module 219 may extract elements and connectivity of elements from the layout data (130 of FIG. 1) of the integrated circuit through the LVS rule file 211_5. In some embodiments, the analysis module 219 may perform the operation of LVS analysis (S40 of FIG. 1). Specifically, the analysis module 219 may generate an LVS netlist 140 from the layout data 130, and compare the LVS netlist 140 with a schematic netlist extracted from the layout, thereby analyzing and verifying whether the layout generated by the design module 213 corresponds to the schematic diagram.

The processor 215 according to some embodiments may control and support various operations performed in the design system 200. For example, the processor 215 may include a microprocessor, an application processor AP, a digital signal processor DSP, and/or a graphic processing unit GPU, etc. Although only one processor 215 is illustrated in FIG. 2, in some embodiments, the design system 200 may include multiple processors. In some embodiments, one of the multiple processors may execute each of the design module 213, the LLE module 217, and the analysis module 219. In some embodiments, different ones of the multiple processors may execute different ones of the design module 213, the LLE module 217, and the analysis module 219.

FIG. 3 is a block diagram of an LLE module according to some embodiments.

In some embodiments, the LLE module 300 may use the LLE model to calculate variations in physical characteristics of transistors within an integrated circuit depending on LLE parameters.

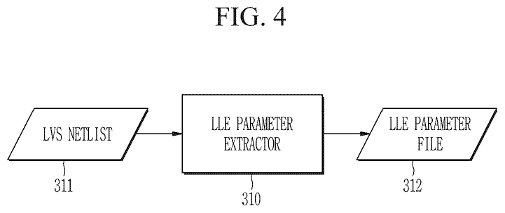

Referring to FIG. 3, the LLE module 300 may include an LLE parameter extractor 310 and an LLE calculator 320. Specifically, the LLE parameter extractor 310 extracts the plurality of transistors and values of various LLE parameters corresponding to the plurality of transistors from the LVS netlist (140 in FIG. 1). The LLE calculator 320 may input the values of the LLE parameters into the LLE model, thereby enabling analysis of LLE for transistors in the integrated circuit according to the LLE parameters. A specific description of the LLE parameter extractor 310 and the LLE calculator 320 is described with reference to FIG. 4 to FIG. 12.

FIG. 4 is a diagram for explaining an LLE parameter extractor according to some embodiments.

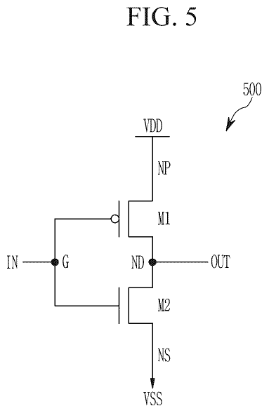

Referring to FIG. 4, the LLE parameter extractor 310 may receive an LVS netlist 311 and output an LLE parameter file 312. The LLE parameter extractor 310 may receive the LVS netlist 311 including patterns of the layout and connection information between the patterns, and may output an LLE parameter file 312 by extracting LLE parameters from the LVS netlist 311. An exemplary description of the LVS netlist 311 is described below with reference to FIG. 5 to FIG. 7.

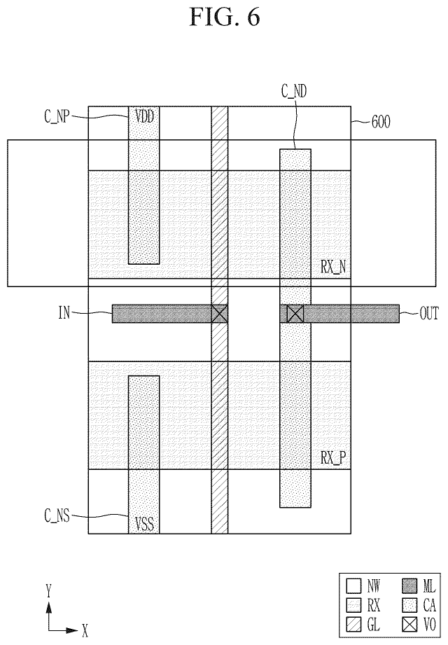

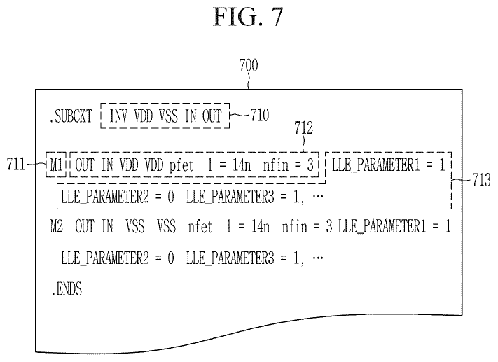

FIG. 5 is a circuit diagram of an exemplary standard cell, and FIG. 6 is a layout diagram of a standard cell according to the circuit diagram of FIG. 5. Specifically, FIG. 5 and FIG. 6 are circuit diagrams and layout diagrams for explaining the LVS netlist of FIG. 7, according to some embodiments.

Referring to FIG. 5, a circuit diagram of a C-type transistor 500 including a P-type transistor M1 and an N-type transistor M2 is shown. Specifically, a P-type transistor M1 and an N-type transistor M2 are connected through a node ND, and a C-type transistor 500 outputs a signal through the node ND. The name of the wire (net name) connected to the node ND that outputs the signal is assumed to be ‘OUT’.

The gate of the P-type transistor M1 is connected to the gate of the N-type transistor M2. The C-type transistor 500 receives a signal through the gate of the P-type transistor M1 and the gate of the N-type transistor M2. The name of the wire connected to the gate G that receive the signal is assumed to be ‘IN’.

The first terminal NP of the P-type transistor M1 is connected to the first power supply voltage VDD, and the first terminal NS of the N-type transistor M2 is connected to the second power supply voltage VSS.

Referring to FIG. 6, a standard cell 600 may include active regions RX extending in a first direction (e.g., an X direction). The active regions RX extending in the first direction may be arranged along a second direction (e.g., a Y direction) and may be parallel to each other. An active pattern formed in the active region RX may intersect with a gate line GL to form a transistor. For example, an N-type transistor (M2 in FIG. 5) may be formed in an active region RX_P, and a P-type transistor (M1 in FIG. 5) may be formed in an active region RX_N formed in an N-well doped with an N-type impurity.

The gate line GL may extend in the second direction (Y direction) and may be composed of any material having electrical conductivity. Referring to FIG. 5 together with FIG. 6, the gate line GL may correspond to the gate G of the P-type transistor M1 and the N-type transistor M2. That is, the gate line GL may correspond to an input pin of a standard cell 600 and may be connected to a wire IN. The gate line GL may be connected to the first metal layer ML through a via V0. The gate line GL may receive signals from the outside (e.g., another standard cell) through a via V0 and the first metal layer ML. However, the layout is not limited to that illustrated in FIG. 6, and in some embodiment, additional metal layers or vias may be connected between the gate line GL and the via V0.

The contact layer CA may be placed on the active region RX and electrically connected to the active region RX. The contact layer CA may be a source/drain contact and make electrical contact with the corresponding part of the transistor, i.e., the source/drain region. The contact layer CA may extend in the second direction (Y direction). A contact layer C_ND corresponding to a node ND to which a P-type transistor M1 and an N-type transistor M2 are connected may correspond to an output pin of a standard cell 600 and may be connected to a wire OUT. The node ND may be connected to the first metal layer ML through a via V0. A node ND may output signals to the outside (e.g., another standard cell) through a via V0 and the first metal layer ML.

Each of the contact layers C_NP, C_NS corresponding to the first terminal NP of the P-type transistor M1 and the first terminal NS of the N-type transistor M2 may be connected to the first power supply voltage VDD and the second power supply voltage VSS.

The standard cell 600 of FIG. 6 may correspond to a C-type transistor (500) including a P-type transistor M1 including a gate connected to a wire IN and receiving a signal from the outside, a first terminal connected to a first power supply voltage VDD, and a second terminal connected to a wire OUT and outputting a signal, and an N-type transistor M2 including a gate connected to a wire IN and receiving a signal from the outside, a first terminal connected to a second power supply voltage VSS, and a second terminal connected to a wire OUT and outputting a signal.

FIG. 7 shows a schematic LVS netlist corresponding to the circuit diagram of FIG. 5 and the layout diagram of FIG. 6, according to some embodiments.

In the operation of LVS analysis (S40 of FIG. 1), the integrated circuit design tool may generate the LVS netlist 700 from the layout patterns of FIG. 6.

Referring to FIG. 7, the LVS netlist 700 describes the connection information for each transistor in the integrated circuit. The LVS netlist 700 may define standard cells within an integrated circuit and define wire information 710 to which the standard cells are connected. Specifically, the LVS netlist 700 is a standard cell and wire information 710 connected to the standard cell, which may define a C-type transistor (INV) (i.e., an inverter) and the name of the wire connected to the inverter (INV) (i.e., VDD, VSS, IN, OUT).

The LVS netlist 700 may define various information for each transistor within the standard cells. Specifically, the LVS netlist 700 may include a name (M1) 711 of the transistor included in the C-type transistor (500 in FIG. 5), a name of the wire connected to the transistor (OUT, IN, VDD), a transistor type (pfet), a gate length (1=14 nm), and a number of fins (nfin=3) 712.

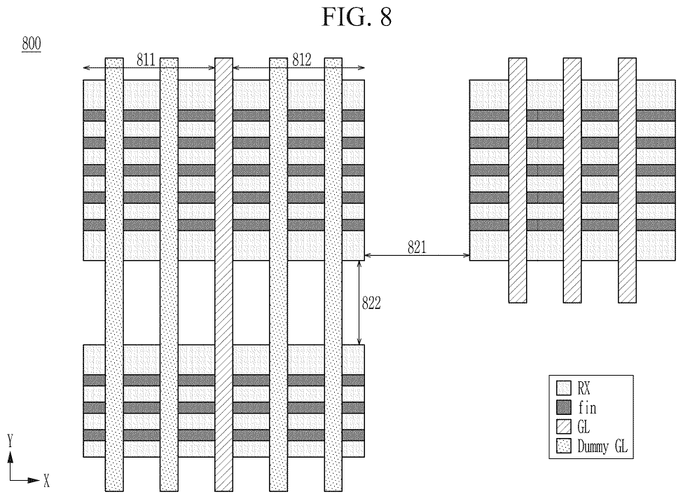

In some embodiments, the LVS netlist 700 may further include LLE parameter information 713 of the transistors within the integrated circuit. The surrounding layout may affect to the characteristic of transistors (e.g., M1) within the integrated circuit. Accordingly, the LVS netlist 700 may obtain LLE parameters LLE_PARAMETER1, LLE_PARAMETER2, LLE_PARAMETER3 that cause LLE generated by the surrounding layout from the layout pattern, and the values of the LLE parameters. The LLE parameters may be predetermined. A detailed description of the predetermined LLE parameters is described with reference to FIG. 8.

FIG. 8 is a diagram for explaining the LLE parameters. Specifically, the layout of an arbitrary region within an integrated circuit is illustrated to explain the LLE parameters.

As described above, as semiconductor processes become more refined, the electrical characteristics of transistors within an integrated circuit may vary depending on their surrounding structures (e.g., adjacent components, metal wiring, transistor density, etc.). Therefore, it is advantageous to prevent LLE by identifying LLE parameters that cause LLE in advance during the layout process and change the layout accordingly.

There may be a variety of LLE parameters that affect the characteristics of transistors within an integrated circuit. For example, LLE parameters may include a presence or absence of an active region, a shape of the active region, a distance from a gate line to an N-well, etc. Here, some LLE parameters are briefly described to help in understanding, but the types of LLE parameters are not limited to these.

Referring to FIG. 8, the integrated circuit 800 may include a plurality of active regions RX and at least one fin extending in a predetermined direction on the active region RX, a gate line GL extending in a direction perpendicular to the fin, and a dummy gate line extending in a direction parallel to the gate line GL.

In some embodiments, the LLE parameters may include a length of the source 811 and a length of the drain 812 in the first direction. As the integration density of integrated circuits increases, a shallow trench isolation STI process is introduced, and due to the STI structure, the length of the source 811 and the length of the drain 812 affect the characteristics of the transistor. Since the length of the source 811 and the length of the drain 812, that is, the distance from the gate line GL to the insulating region STI, directly affects a stress of the transistor, the length of the source 811 and the length of the drain 812 must be maintained at a threshold length or longer. The threshold length may be predetermined. Therefore, the LVS netlist (700 of FIG. 7) may include the length of the source 811 and the length of the drain 812 of the transistor as LLE parameters that affect the characteristics of the transistor.

In some embodiments, the LLE parameters may include a spacing 821 between active regions in a first direction and a spacing 822 between active regions in a second direction perpendicular to the first direction. As the integration density of integrated circuits increases, a parasitic capacitance increases when the spacing between active regions is close, which may affect the characteristics of the transistor. That is, since the spacing between active regions directly affects the stress of the transistor, the spacing between active regions must be maintained at a threshold spacing or longer. The threshold spacing may be predetermined. Therefore, the LVS netlist 700 may include the spacing between active regions around the transistor as an LLE parameter that affects the characteristics of the transistor.

As described above, there may be various LLE parameters that affect the characteristics of a transistor, and the LVS netlist 700 may obtain, from a layout pattern, values of the various LLE parameters that cause LLE. The LVS netlist 700 may include values for various LLE parameters around transistors within an integrated circuit.

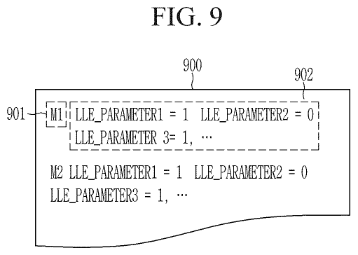

FIG. 9 shows an exemplary LLE parameter file output by the LLE parameter extractor, according to some embodiments.

Referring to FIGS. 4 and 9, the LLE parameter extractor 310 may extract an LLE parameter file 312 from an LVS netlist 311. As described above, the LVS netlist 311 may obtain the values of LLE parameters of each transistor in the integrated circuit from the layout pattern and define the LLE parameters for each transistor. Accordingly, the LLE parameter extractor 310 may identify LLE parameters defined in the LVS netlist 311 and output an LLE parameter file 312.

Referring to FIG. 7, the LVS netlist 700 may include various information about transistors within an integrated circuit and values of LLE parameters around the transistors. The LLE parameter extractor 310 may identify each transistor and the LLE parameters for each transistor from the LVS netlist 700, and extract each transistor and the LLE parameters for each transistor. The LLE parameter extractor 310 may output an LLE parameter file 900 including the extracted LLE parameters for each transistor, as illustrated in FIG. 9. The LLE parameter file 900 may include a transistor 901 within an integrated circuit and LLE parameters 902 that may affect the characteristics of the transistor.

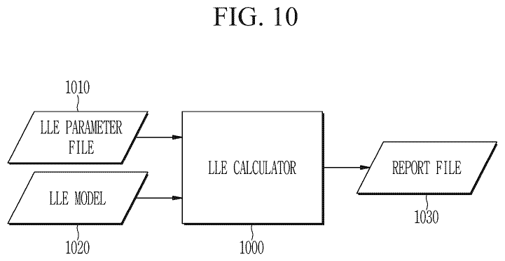

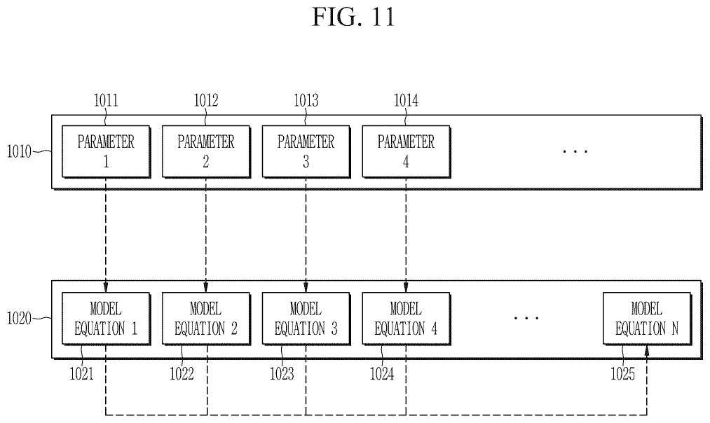

FIG. 10 is a diagram for explaining an LLE calculator according to some embodiments, and FIG. 11 is a diagram for explaining the operation method of the LLE model, according to some embodiments.

Referring to FIG. 10, the LLE calculator 1000 may receive an LLE parameter file 1010 and an LLE model 1020, and output a report file 1030 including the variation values of the characteristics of a transistor by LLE parameters. In some embodiments, the LLE parameter file 1010 may correspond to the LLE parameter file 900 of FIG. 9. The LLE calculator 1000 may calculate variations in physical characteristics of transistors in an integrated circuit based on an LLE parameter file 1010 and an LLE model 1020, and output a report file 1030 including information about variations in physical characteristics of the transistors according to LLE parameter values. That is, the LLE calculator 1000 may calculate variations in physical characteristics for each transistor in an integrated circuit based on the LLE parameters for the transistor indicated in the LLE parameter file 1010 and using the LLE model 1020.

In some embodiments, the LLE model 1020 may be implemented as a function that calculates variations in physical characteristics of a transistor within an integrated circuit according to LLE.

Referring to FIG. 11, the LLE model 1020 may include a plurality of model equations that calculate variations of physical characteristics of a transistor within an integrated circuit according to each LLE parameter. In some embodiments, a number of the plurality of model equations may be equal to the number of LLE parameters. Specifically, each model equation may receive the value of a corresponding one of the LLE parameters, and calculate the variation of the physical characteristics of the transistor according to the corresponding LLE parameter.

In some embodiments, the LLE model 1020 may include a plurality of model equations 1021, 1022, . . . , 1025. Each model equation 1021, 1022, . . . , 1025 may receive a corresponding LLE parameter 1011, 1012, 1013, 1014 in the LLE parameter file 1010, and calculate the variation of the physical characteristics of the transistor by the LLE parameters. For example, among the plurality of model equations in the LLE model 1020, the first model equation 1021 may calculate the variation of the physical characteristics of the transistor by the first LLE parameter 1011, the second model equation 1022 may calculate the variation of the physical characteristics of the transistor by the second LLE parameter 1012, the third model equation 1023 may calculate the variation of the physical characteristics of the transistor by the third LLE parameter 1013, and the fourth model equation 1024 may calculate the variation of the physical characteristics of the transistor by the fourth LLE parameter 1014. The LLE model 1020 may include model equations corresponding to the number of LLE parameters. However, it embodiments are not limited to this.

In some embodiments, at least one model equation among the plurality of model equations within the LLE model may sum the variation of physical characteristics of the transistor due to multiple LLE parameters. Specifically, at least one among the plurality of model equations within the LLE model may add up the variation of the physical characteristics of the transistor calculated by other model equations, and output the added value as the variation value of the physical characteristics of the transistor by the LLE parameters. For example, the Nth model equation 1025 may add up the variation of the physical characteristics of the transistor calculated by the remaining model equations (e.g., the first to N−1th model equations) except for the Nth model equation 1025, and output the added value as the variation value of the physical characteristics of the transistor by the LLE parameters 1011, 1012, 1013, 1014. In an embodiment, the physical characteristics of the transistor may include variations in a threshold voltage of the transistors and variations in a mobility of the transistors.

In some embodiments, the LLE calculator 1000 may output a report file 1030 that includes information about variations of physical characteristics of transistors according to LLE parameter values.

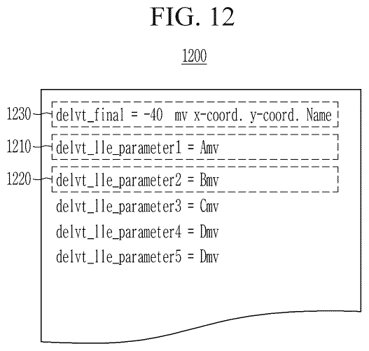

FIG. 12 shows an exemplary report file output by the LLE calculator, according to some embodiments.

Referring to FIG. 11 and FIG. 12, the report file 1200 may include variation values of physical characteristics of transistors calculated by each LLE model equation. Here, the report file 1200 is described as outputting the change in threshold voltage as a physical characteristic of transistors by way of an example, but the physical characteristics of the transistors output by the report file 1200 are not limited thereto.

In some embodiments, the report file 1200 may include the variation in threshold voltage of transistors by LLE parameters. Specifically, the first model equation (1021 of FIG. 11) may calculate the variation in the threshold voltage of the transistor by the first LLE parameter (1011 of FIG. 11), and the LLE calculator (1000 of FIG. 10) may output a report file 1200 including the variation in the threshold voltage of the transistor 1210 by the first LLE parameter 1011. The second model equation (1022 of FIG. 11) may calculate the variation in the threshold voltage of the transistor due to the second LLE parameter (1012 of FIG. 11), and the LLE calculator 1000 may output a report file 1200 including the variation in the threshold voltage of the transistor 1220 due to the second LLE parameter 1012. The Nth model equation (1025 of FIG. 11) may add up the variation in the threshold voltage of the transistor by the remaining model equations, and the LLE calculator 1000 may output a report file 1200 including information 1230 such as the variation in the threshold voltage of the transistor by the sum of a plurality of LLE parameters. Referring to FIG. 12, information 1230 may include, but is not limited to, a change in threshold voltage of a transistor by LLE parameters (delvt_final), coordinate information of the corresponding transistor (x-coord, y-coord), and a name of the corresponding transistor (Name).

According to some embodiments, the integrated circuit design tool may output a report file 1200 so that the integrated circuit design tool can further evaluate and correct the variation in the physical characteristics of transistors due to the LLE parameters. The integrated circuit design tool may output a report file 1200 so that the integrated circuit design tool can determine LLE parameters that affect the physical characteristics of transistors among the plurality of LLE parameters. The integrated circuit design tool may output a report file 1200 so that the integrated circuit design tool can determine LLE parameters that affect the physical characteristics of transistors among the plurality of LLE parameters, and correct the layout corresponding to the identified LLE parameters. In some embodiment, the processor 215 of the design system may read the information in the report file 1200, determine the LLE parameters that effect the physical characteristics of a transistor, and modify the layout of the transistor by, for example, moving the transistor in the layout, moving one or more of other transistors in the layout, or changing connections among the transistors in the layout in order to mitigate the LLE. According to some embodiments, there is an advantage in that by identifying the LLE for transistors prior to the operation of post-layout simulation (S60 of FIG. 1) and correcting the LLE in advance by the user or by the processor 215, unnecessary iterations may be reduced and the Turn-Around Time (TAT) may be reduced.

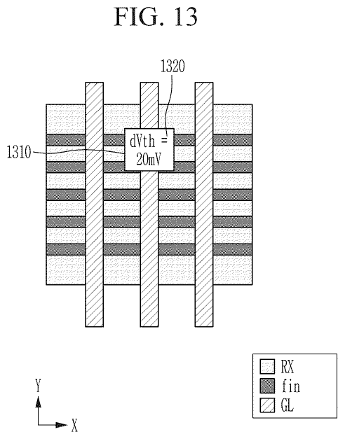

FIG. 13 is a diagram for explaining a result output method of an integrated circuit design tool according to some embodiments.

In some embodiments, a report file 1200 output by the LLE calculator may include the variation of the threshold voltage of the transistor due to the LLE parameters and coordinate information of the corresponding transistor. The integrated circuit design tool may display the variation of the threshold voltage of the corresponding transistor on the layout, based on the information in the report file 1200.

Referring to FIG. 13, the layout of a region within an integrated circuit designed by an integrated circuit design tool is shown. An active pattern formed in an active region RX may intersect a gate line GL to form a transistor, and the electrical characteristics of the transistor may vary depending on the surrounding structure.

In some embodiments, the integrated circuit design tool may obtain the variation in threshold voltage of a transistor by LLE parameters and coordinate information of the corresponding transistor from a report file 1200. The integrated circuit design tool may identify a transistor whose threshold voltage variation is greater than a threshold value from the report file 1200 and highlight an area of the corresponding transistor based on coordinate information of the transistor in the report file 1200. The threshold value may be predetermined. For example, an integrated circuit design tool may highlight regions 1310 of transistors having a threshold voltage variation greater than a threshold value to visually distinguish them from transistors having a threshold voltage variation less than a threshold value. In an exemplary embodiment, a region of transistors having a threshold voltage variation less than a threshold value may be represented by a first color, and a region of transistors having a threshold voltage variation greater than the threshold value may be represented by a second color different from the first color.

In some embodiments, the integrated circuit design tool may insert text 1320 indicating the variation of threshold voltage of the transistor in the highlighted region 1310 of the transistor where the variation in threshold voltage is greater than a threshold value. For example, the integrated circuit design tool may obtain the variation of the threshold voltage of each transistor from the report file 1200 and insert text 1320 indicating the variation in the threshold voltage of the transistor into the highlighted area 1310 of the corresponding transistor. This insertion allows users of integrated circuit design tools to intuitively understand the variation of the physical characteristics of transistors due to LLE parameters on the layout.

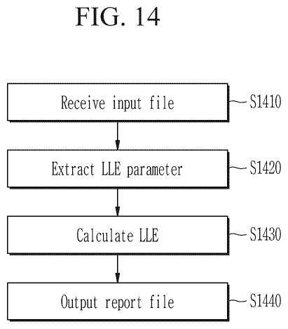

FIG. 14 is a flowchart for explaining an LLE analysis method of an LLE module according to some embodiments.

Referring to FIG. 14, to analyze LLE for transistors in an integrated circuit, the LLE module may receive an input file S1410. The LLE module may receive as an input file an LVS netlist containing layout patterns, connection information between the patterns, and LLE parameters.

In some embodiments, LLE module may extract LLE parameters from the LVS netlist S1420. The LVS netlist may include values of LLE parameters for each transistor in the integrated circuit, and the LLE module may extract the LLE parameters for each transistor from the LVS netlist.

In some embodiments, the LLE module may calculate the LLE for each transistor S1430. Specifically, the LLE module may calculate the variation of physical characteristics of transistors according to the values of LLE parameters using the LLE model. The LLE model may include the plurality of model equations, each of which may calculate variations of physical characteristics of transistors due to corresponding LLE parameters. The LLE model may input LLE parameters corresponding to each of the plurality of model equations and obtain variation values of physical characteristics of transistors according to the LLE parameters. Here, the physical characteristics of the transistors may include, but are not limited to, variations of the threshold voltage of the transistor, variations of mobility of the transistor, etc.

In some embodiments, the LLE module may output a report file S1440. Specifically, the LLE module may output a report file including a value of variation of the physical characteristics of the transistor by each LLE parameter and a value of the sum of variation in the physical characteristics of the transistor by each LLE parameter.

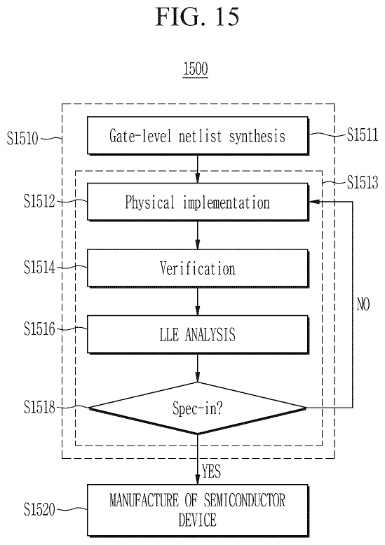

FIG. 15 is a flowchart showing a method for designing and manufacturing an integrated circuit according to some embodiments.

Referring to FIG. 15, a design and manufacturing method 1500 of an integrated circuit may include a design operation of an integrated circuit S1510 and a manufacturing operation of a semiconductor device S1520.

In some embodiments, the design operation of the integrated circuit S1510 may include an operation of gate level netlist synthesis S1511 and an operation of physical design S1513. The design operation of the integrated circuit S1510 may be performed by an integrated circuit design tool. In the operation of gate-level netlist synthesis S1511, the integrated circuit design tool may perform logic synthesis to generate a gate-level netlist from RTL data written as an Hardware Description Language (HDL) such as VHSIC Hardware Description Language (VHDL) and Verilog, based on information about operating conditions (e.g., operating voltage, etc.), threshold voltages, and standard cells of the integrated circuit determined according to specifications of the integrated circuit.

In some embodiments, the operation of physical design S1513 may include an operation of physical implementation S1512, an operation of verification S1514, and an operation of LLE analysis S1516. The operation of physical implementation S1512 may include a placement operation for placing standard cells based on a gate level netlist generated in the operation of gate-level netlist synthesis S1511, a routing operation for connecting pins of the standard cells, etc., and the integrated circuit design tool may generate layout data defining the standard cells and wires, etc. placed in the operation of physical implementation S1512. The layout data may have a format such as GDSII and may include geometric information of cells and interconnections.

In some embodiments, the operation of verification S1514 may be an operation of verifying and modifying the generated layout. Verification items may include Static Timing Analysis STA, which verifies that the layout satisfies the timing conditions of the design, Design Rule Check DRC, which verifies that the layout is properly aligned with the design rules, Electronic Rule Check ERC, which verifies that the layout is properly aligned without internal electrical disconnection, and LVS, which verifies that the layout matches the netlist.

In some embodiments, LVS is performed to verify that the generated layout corresponds to the schematic. The integrated circuit design tool may generate an LVS netlist containing the patterns of the layout and the connection information between the patterns from the layout data, and compare the LVS netlist with the schematic netlist that defines the connection relationships of the devices in the layout. An LVS netlist may include, but is not limited to, connection information for layout patterns within an integrated circuit, LLE parameters, etc.

In some embodiments, the operation of LLE analysis S1516 may be performed based on the LVS netlist generated in the operation of verification S1514. In the operation of LLE analysis S1516, each operation of FIG. 14 may be performed. The operation of LLE analysis S1516 may output changes of the physical characteristics of each transistor in an integrated circuit by LLE parameters as a report file.

In some embodiments, the integrated circuit design tool may determine whether the amount of variation of the physical characteristics of each transistor within the integrated circuit is less than or equal to a threshold value based on a report file generated as a result of the LLE analysis. If an integrated circuit includes transistors whose the amount of variation of physical characteristics exceeds a threshold value, the integrated circuit design tool may instruct to modify that value. An integrated circuit design tool may instruct the user to modify LLE parameters that change the physical characteristics of transistors by extracting those transistors whose the amount of variation of physical characteristic exceeds a threshold value or by highlighting those transistors on the layout. Based on this, a user of the integrated circuit design tool may control the integrated circuit design tool to re-perform at least some operations during the operation of physical implementation S1512.

The operation of manufacturing of the semiconductor device S1520 may include a plurality of operations for manufacturing a mask and forming a semiconductor package.

The operation of manufacturing of the semiconductor device S1520 may include an operation of performing optical proximity correction OPC, etc. on layout data generated in the design operation of an integrated circuit S1510 to generate mask data for forming various patterns in a plurality of layers, and an operation of manufacturing a mask using the mask data. In the operation of manufacturing of the semiconductor device S1520, various types of exposure and etching processes may be performed repeatedly. Through these processes, the shapes of patterns configured during layout design may be sequentially formed on a silicon substrate.

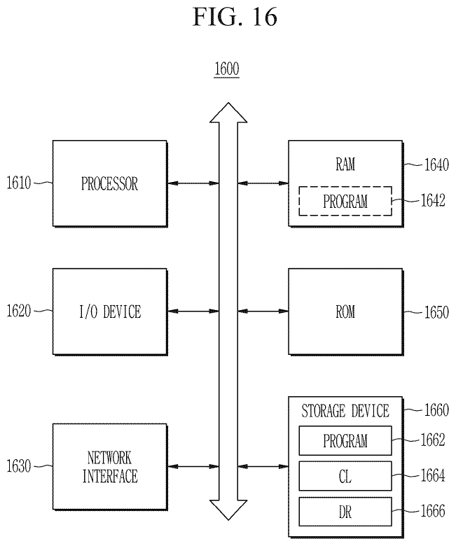

FIG. 16 is a block diagram showing a design system for an integrated circuit according to some embodiments.

Referring to FIG. 16, the design system 1600 may include a processor 1610, an input/output (I/O) device 1620, a network interface 1630, a random access memory (RAM) 1640, a read only memory (ROM) 1650, and a storage device 1660.

The design system 1600 may be a computing system, and may be a stationary computing system, such as a desktop computer, a workstation, a server, or a portable computing system, such as a laptop computer.

The processor 1610 may include a core capable of executing any instruction set (e.g., IA-32 (Intel Architecture-32), 64-bit extended IA-32, x86-64, PowerPC, Sparc, MIPS, ARM, IA-64, etc.). For example, the processor 1610 may access memory, i.e., RAM 1640 or ROM 1650, through the bus and execute instructions stored in the RAM 1640 or ROM 1650. RAM 1640 may store all or part of a program 1642 corresponding to the design module 213, LLE module 217, and analysis module 219 of FIG. 2, and the program 1642 may cause the processor 1610 to perform operations for designing an integrated circuit.

The RAM 1640 may store all or part of a program 1642, and the program 1642 may cause the processor 1610 to perform operations for designing an integrated circuit. In other words, the program 1642 may include a plurality of instructions and/or procedures executable by the processor 1610 and the plurality of instructions and/or procedures included in the program 1642 may cause the processor 1610 to perform operations for designing an integrated circuit according to the embodiments described above. The procedure may refer to a series of instructions for performing a specific task. A procedure may also be called a function, routine, subroutine, or subprogram. Each of the procedures may process data provided externally or data generated by other procedures.

The storage device 1660 may store the program 1642, the cell library 1664 and the design rules 1666, and all or part of the program 1642 may be loaded from the storage device 1660 into the RAM 1640 before the program 1642 is executed by the processor 1610.

The storage device 1660 may store files written in a programming language, or all or part of a program 1642 generated by a compiler or the like may be loaded into the RAM 1640.

The storage device 1660 may store data to be processed by the processor 1610 or data processed by the processor 1610. That is, the processor 1610 may generate new data by processing data stored in the storage device 1660 according to the program 1642, and may also store the generated data in the storage device 1660.

The input/output device 1620 may include an input device such as a keyboard, a pointing device, etc., and may include an output device such as a display device, a printer, etc. For example, a user may trigger execution of a program 1642 by a processor 1610 through an input/output device 1620, or may check the highlighted layout or text of FIG. 13 through a display device.

The network interface 1530 may provide an access for an external network of design system 1600. For example, a network may include a number of computing systems and communication links, which may include wired links, optical links, wireless links, or any other form of links.

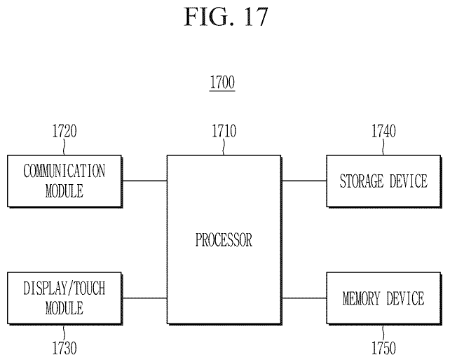

FIG. 17 is a block diagram showing an electronic system according to some embodiments.

Referring to FIG. 17, the electronic system 1700 may include a processor 1710, a communication module 1720, a display/touch module 1730, a storage device 1740, and a memory device 1750. For example, the electronic system 1700 may be any mobile system or computing system.

The processor 1710 may control the overall operation of the electronic system 1700. The processor 1710 may execute an operating system, applications, etc. The communication module 1720 may be implemented to control wired communication and/or wireless communication with the outside. The display/touch module 1730 may be implemented to display data processed by the processor 1710 or receive data from a touch panel. The storage device 1740 may store the data of user. The memory device 1750 may temporarily store data for processing operations of the electronic system 1700 and may store all or part of a program corresponding to the design module 213, LLE module 217, and analysis module 219 of FIG. 2, and the program may cause the processor 1710 to perform operations for designing an integrated circuit according to the various embodiments described above.

Various embodiments may be usefully utilized in the design of any electronic device and system. For example, various embodiments may be more usefully applied to electronic devices such as computers, laptops, cellular phones, smart phones, MP3 players, PDAs (Personal Digital Assistants), PMPs (Portable Multimedia Players), digital TVs, digital cameras, portable game consoles, navigation devices, wearable devices, Internet of Things (IoT) devices, Internet of Everything (IoE) devices, e-books, Virtual Reality (VR) devices, Augmented Reality (AR) devices, and the like.

Although various embodiments have been described in detail above with reference to the drawings, the scope of the present disclosure is not limited thereto, and various modifications and improvements made by those skilled in the art are included in the scope defined in the following claim.

What is claimed is:

1. An integrated circuit design system comprising:
a storage device configured to store a cell library including layout information of standard cells and a local layout effect (LLE) model; and
at least one processor configured to execute a design module to cause the at least one processor to generate a layout of an integrated circuit including the standard cells based on the cell library, extract a plurality of LLE parameters for a transistor in the integrated circuit from a layout versus schematic (LVS) netlist corresponding to the layout, and calculate variations of physical characteristics of the transistor according to the plurality of LLE parameters based on the plurality of LLE parameters and the LLE model.

2. The integrated circuit design system of claim 1, wherein:
the LLE model includes a plurality of model equations corresponding respectively to the plurality of LLE parameters.

3. The integrated circuit design system of claim 2, wherein:
each of the plurality of model equations is configured to receive, as an input, a corresponding LLE parameter among the plurality of LLE parameters and operate on the corresponding LLE parameter to calculate a variation of the physical characteristics of the transistor according to the corresponding LLE parameter.

4. The integrated circuit design system of claim 3, wherein:
the design module is executed to output the variation of the physical characteristics of the transistor according to the corresponding LLE parameter calculated by the each of the plurality of model equations.

5. The integrated circuit design system of claim 4, wherein:
the design module is executed to further output the variations of the physical characteristics of the transistor according to the plurality of LLE parameters.

6. The integrated circuit design system of claim 3, wherein:
one model equation among the plurality of model equations is configured to sum the variations of the physical characteristics of the transistor calculated by remaining model equations among the plurality of model equations.

7. The integrated circuit design system of claim 1, wherein:
the LVS netlist includes connection information of the transistor and the plurality of LLE parameters that cause the local layout effect for the transistor.

8. The integrated circuit design system of claim 1, wherein:
the plurality of LLE parameters include one or more of a source length of a source of the transistor, a drain length of a drain of the transistor, and a spacing between active regions of the transistor on the layout.

9. The integrated circuit design system of claim 1, wherein:
the physical characteristics of the transistor include a threshold voltage of the transistor or a mobility of the transistor.

10. A method for design an integrated circuit, the method comprising:
generating a layout design for the integrated circuit;
obtaining a local versus schematic (LVS) netlist corresponding to the layout design;
extracting a plurality of local layout effect (LLE) parameters for transistors in the integrated circuit from the LVS netlist;
calculating variations of physical characteristics of the transistors based on the plurality of LLE parameters and an LLE model; and
performing a post-layout simulation for the layout design.

11. The method of claim 10, wherein the extracting comprises:
identifying the transistors in the integrated circuit and LLE parameters for the transistors from the LVS netlist; and
outputting an LLE parameter file including the transistors and the LLE parameters for the transistors.

12. The method of claim 10, wherein the calculating comprises, for each of the transistors in the integrated circuit:
inputting a corresponding LLE parameter among the plurality of LLE parameters into a corresponding one of a plurality of model equations in the LLE model; and
obtaining the variations of the physical characteristics of the transistor by the corresponding LLE parameters from the each of plurality of model equations.

13. The method for design an integrated circuit of claim 12, wherein one model equation of the plurality of model equations is configured to calculate a sum value of the variations of the physical characteristics of the transistor from remaining model equations of the plurality of model equations, and
the method further comprises:
obtaining the sum value of the variations of the physical characteristics of the transistor from the one model equation.

14. The method for design an integrated circuit of claim 13, further comprising:
identifying a transistor from among the transistors of the integrated circuit whose sum value is equal to or greater than a threshold value.

15. An integrated circuit design system comprising:
a storage device configured to store a cell library including layout information of standard cells and a local layout effect (LLE) model;
at least one processor configured to execute:
a design module to cause the at least one processor to generate a layout of an integrated circuit including the standard cells based on the cell library;
an analysis module configured to generate a local versus schematic (LVS) netlist corresponding to the layout; and
a LLE module configured to perform an LLE analysis for transistors in the integrated circuit, based on LLE parameters extracted from the LVS netlist and the LLE model.

16. The integrated circuit design system of claim 15, wherein the LLE module comprises:
a LLE parameter extractor configured to receive the LVS netlist and extract the LLE parameters for the transistors from the LVS netlist; and
a LLE calculator configured to calculate variations of physical characteristics of the transistors according to the LLE parameters, based on the LLE parameters and the LLE model.

17. The integrated circuit design system of claim 16, wherein:
the LLE parameter extractor is configured to identify the transistors and the LLE parameters corresponding to the transistors from the LVS netlist, and output the transistors and the LLE parameters corresponding to the transistors.

18. The integrated circuit design system of claim 16, wherein:
the LLE calculator is configured to, for each of the transistors in the integrated circuit, input corresponding LLE parameters among the plurality of LLE parameters into each of a plurality of model equations within the LLE model, and output the variations of physical characteristics of the transistor according to the LLE parameters obtained from the each of the plurality of model equations.

19. The integrated circuit design system of claim 18, wherein:
the LLE calculator is configured to sum up the variations of physical characteristics of the transistor according to the LLE parameters obtained from the each of the plurality of model equations.

20. The integrated circuit design system of claim 18, wherein:
the variations of physical characteristics include variations of a threshold voltage or variations of a mobility.
